(19) United States
(12) Patent Application Publication
(10) Pub. No.: US 2005/0176264 A1
(43) Pub. Date: Aug. 11, 2005

(54) Process of forming silicon-based nanowires

(76) Inventors: Ming-Shyong Lai, Hsinchu (TW); Chih-Jen Lin, Hsinchu (TW); Hung-Cheng Chen, Hsinchu (TW); Jyh-Chung Wen, Hsinchu (TW)

Correspondence Address: HARNESS, DICKEY & PIERCE, P.L.C., P.O. BOX 8910, RESTON, VA, 20195, US

(21) Appl. No.: 10/918,479

(22) Filed: Aug. 16, 2004

(30) Foreign Application Priority Data
Feb. 11, 2004 (TW) 93103228

(51) Int. Cl. H01L 21/26

(52) U.S. Cl. 438/800

(57) ABSTRACT

A process of forming silicon-based nanowires heats high-surface-oxygen-content silicon powders to initiate vapor-solid reaction to form nanowires. The reaction gas is charged to react with the Si powders to form the silicon-based nanowires such as silicon nanowires or SiC nanowires. With control of the reaction gas, the components of the nanowires can be exactly controlled without the addition of metallic catalysts. Thereby, the nanowires can be made with reduced cost.

### BACKGROUND OF THE INVENTION

1. Field of Invention

The present invention relates to a process of forming silicon-based nanowires, and more particularly to a process of forming silicon-base nanowires in mass production.

2. Related Art

When the structural dimension of material is reduced to a nanometer (nano) scale, most of the atoms locate at the surface of the material, which provides a special surface effect, volume effect and quantum effect, and the optical, thermal, electric, magnetic and mechanic properties of the material change significantly. The nano material includes nano powders, nano wires, nano films, and nano blocks. Various processes of forming the above nano material have been proposed. Usually, expensive equipment and complex processes are required, particularly for one-dimensional or two dimensional material having special shapes, which makes the massive production of the nano material difficult.

For the nanowires as examples, template auxiliary growth is commonly used in which nano porous material is made as a template, and chemical processes such as a chemical vapor position, a solution chemical method, a sol-gel method or an electroplating method are used to fill up the pores in the template. The nano templates can be made by various processes and materials such as anodic alumina membranes (AAM) auxiliary growth, using nano porous aluminum oxide templates. Many researches are about using carbon fine tubes or porous polymeric substrate templates. However, there are some problems occurring in the template auxiliary growth, such as the exclusive template producing method, the need of post treatments such as heat treatment, easy bonding of the nano structure to the template, and difficulty of releasing the nano structure.

Furthermore, under the vapor-liquid-solid reaction mechanism, crystalline inorganic wires can be formed with the metal clusters as catalyst. The vapor reactants are absorbed on the catalyst to form a liquid alloy. During the absorption, the supersaturated deposition of the reactants precipitates a one-dimensional structure. Currently, most of the researches all over the world focus on silicon and III/V group semiconductor material to grow nano carbon tubes and semiconductor nanowires by a vapor-liquid-solid (VLS) mechanism, or wide energy-band material such as SiC or GaN. The nanowires can be also grown by a liquid-solid-vapor mechanism. Such a mechanism provides many advantages. For example, the size of the catalyst particles controls the diameter distribution of the nanowires. For both the templates auxiliary growth and liquid-solid-vapor mechanism is used, the production cost and equipment costs are high, which is disadvantageous in mass production.

U.S. Pat. No. 6,221,154 discloses a process of producing SiC nanowires, in which the silicon powders are mixed with silicon oxide powders, using metallic powders as catalyst. After hydrogen is charged to perform chemical vapor deposition, silicon powders and SiC nanowires are obtained. The above technology needs high-purity silicon powders for catalyzation, which also increases the cost. Furthermore, the metallic powders used as catalyst easily contaminate the nanowires.

### SUMMARY OF THE INVENTION

The invention provides a process of forming silicon-based nanowires with low cost. High-surface-oxygen-content Si powders are heated in the vacuum. The reaction gas is charged to react with the Si powders to form the silicon-based nanowires such as silicon nanowires or SiC nanowires. Since no metallic catalysts are needed, low-cost vacuum heating equipment can be used to massively produce high-value nanowires.

In order to achieve the above and other objectives, the process of forming the silicon-based snanowires includes placing high-surface-oxygen-content silicon powders into a heating chamber, wherein the surface oxygen content is more than 6000 ppm; vacuating the chamber to 2×10⁻¹ torr; increasing the temperature of the chamber to a reaction temperature; charging a hydrogen-containing reaction gas in the chamber to form a reaction atmosphere; and cooling down the chamber to form nanowires. The silicon powders have a surface oxygen content ranging from 6000 ppm to 15000 ppm. The reaction temperature is preferably 1100-1350° C. The reaction atmosphere is 30-100 torr. The invention further provides a carbon source in the heating chamber or charging C₂H₂ in the reaction atmosphere.

### BRIEF DESCRIPTION OF THE DRAWINGS

FIG. 1 is a schematic view illustrating a high-pressure water atomizing device;

FIG. 2 is a flow chart of a process of forming high-surface-oxygen-content silicon powders according to one embodiment of the invention;

FIG. 3 is a photo illustrating fur-like silicon carbide nanowires obtained in a first embodiment of the invention;

FIG. 4 is a photo taken by a scanning electronic microscope (SEM);

FIG. 5 shows results of analyzing the nanowires of the invention by using an energy dispersive x-ray (EDX);

FIG. 6 is a SEM photo of nanowires obtained in a second embodiment of the invention;

FIG. 7 shows results of analyzing the nanowires of a second embodiment by using an energy dispersive x-ray (EDX); and

FIG. 8 and FIG. 9 are SEM photos showing the obtained films with different amplification.

### DETAILED DESCRIPTION OF THE INVENTION

In the invention, without the use of any material or metallic catalysts, high-surface-oxygen-content silicon powders are charged into large industrial sintering furnace at proper temperature and atmosphere to conduct a vapor-solid reaction.

High-purity silicon or a silicon carbide nanowire is obtained. The obtained product can be further made into nano sheet with further material selection and process control.

In the invention, metallurgy grade Si ingots are subject to high pressure water atomization to obtain silicon powders, having a particle diameter of 10˜150 μm and a high surface oxygen content.

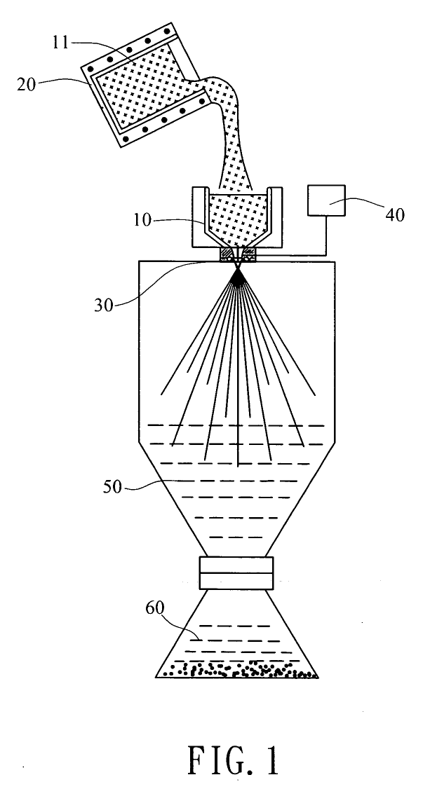

FIG. 1 is a schematic view illustrating a high-pressure water atomizing device and the process thereof. 9 kg silicon ingots are heated at 1650° C. to form melt 11. The melt 11 is charged into a container 10 connected to a nozzle 30 through which the melt 11 enters into an oxygen chamber 50. When the melt 11 enters into an oxygen chamber 50 through the nozzle 30, the nozzle 30 provides oxygen-solvable high-pressure pure water (not shown) to moisturize and oxidize the melt 11. A 6-atm oxygen source 40 is provided halfway the transport path, to increase the oxygen content of the pure water. The moisturized melt drops onto a water reserving area in the oxygen chamber 50, and then cools down to form the high-surface-oxygen-content silicon powders. The silicon powders sediment on a bottom powder collector 60. Then, the powders collected in the collector 60 are dried to obtain 8.2 kg high-surface-oxygen-content silicon powders.

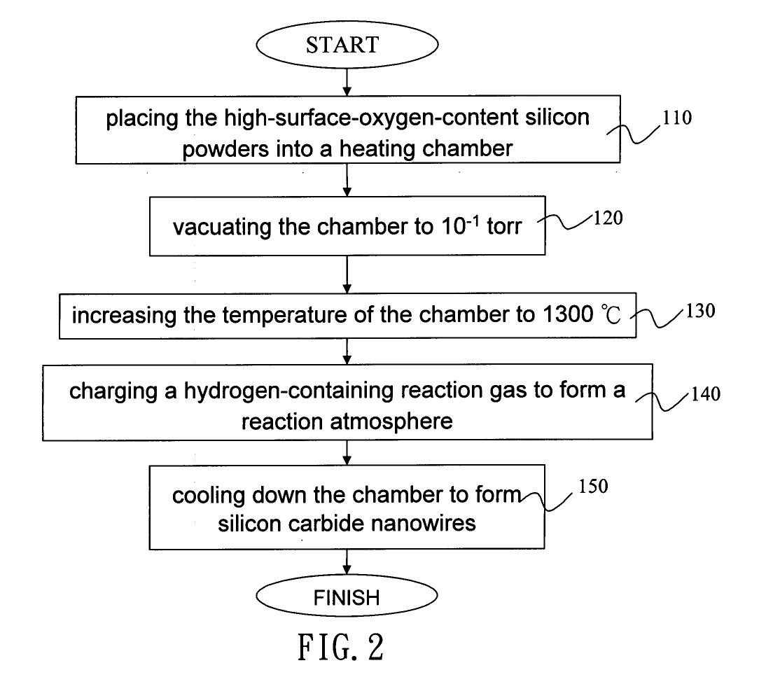

The obtained high-surface-oxygen-content silicon powders are sieved into groups having different average particle diameters. FIG. 2 is a flow chart of a process of forming high-surface-oxygen-content silicon powders according to one embodiment of the invention. As illustrated, the process includes the following steps of placing the high-surface-oxygen-content silicon powders into a heating chamber (step 110); vacuating the chamber to 10⁻¹ torr (step 120); increasing the temperature of the chamber to 1300° C. (step 130); charging a hydrogen-containing reaction gas to form a reaction atmosphere (step 140), the reaction gas including 90% argon and 10% mixed gas of hydrogen and acetylene, the atmosphere pressure being 30-100 torr; finally, cooling down the chamber to form silicon carbide nanowires (step 150).

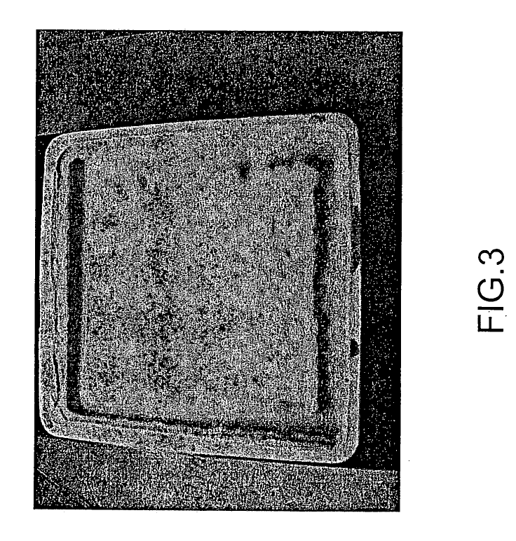

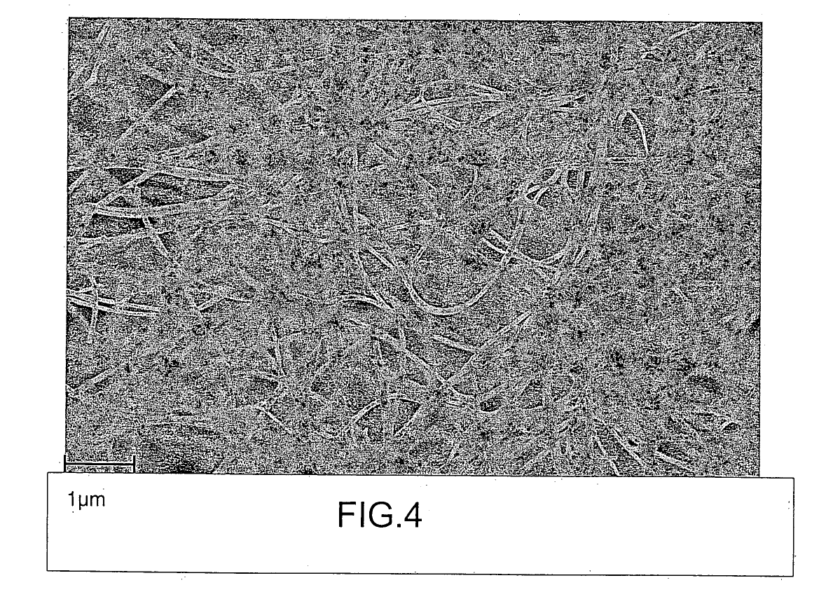

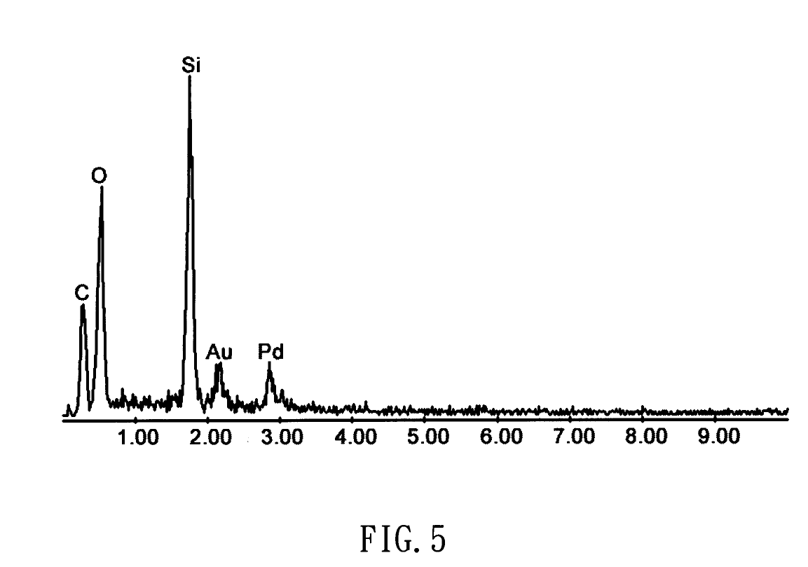

FIG. 3 is a photo illustrating fur-like silicon carbide nanowires obtained in a first embodiment of the invention. As illustrated, it proves that massive production of silicon carbide nanowires can be achieved with low cost according to the process of the invention. FIG. 4 is a photo taken by a scanning electronic microscope (SEM). This photo clearly shows the structure of the nanowires obtained by the invention. FIG. 5 shows results of analyzing the nanowires of the invention by using an energy dispersive x-ray (EDX). As shown in FIG. 5, the nanowires consist of carbon and silicon. Since a specimen needs to coat conductive material such as gold and platinum before being analyzed, the conductive material may be found in the analysis.

The reaction gas can be varied to generate different silicon-based nanowires. In a second embodiment of the invention, 20 g high-surface-oxygen-content silicon powders are placed in the heating chamber. After the heating chamber is vacuated to 10⁻¹-torr, the temperature of the heating chamber increases up to 1250° C. 90% argon and 10% mixed gas of hydrogen and nitrogen are used as the reaction gas. The atmosphere in the chamber is up to 30 to 100 torr. The temperature decreases to obtain a plurality of fur-like nanowires.

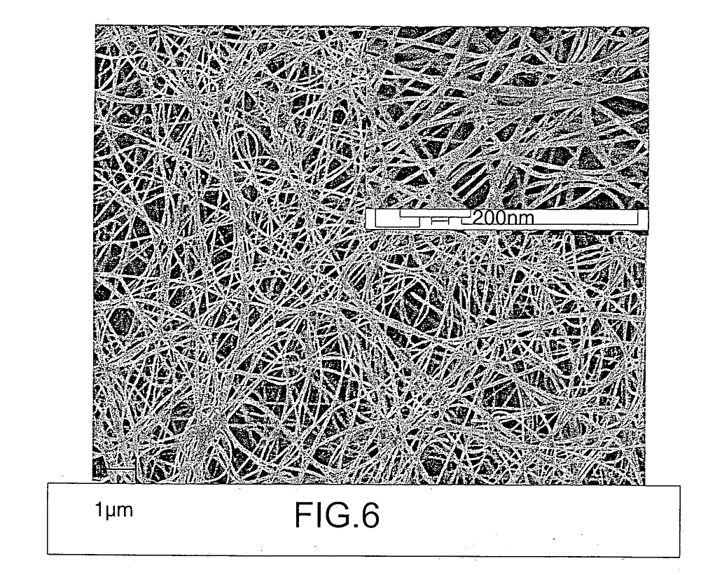

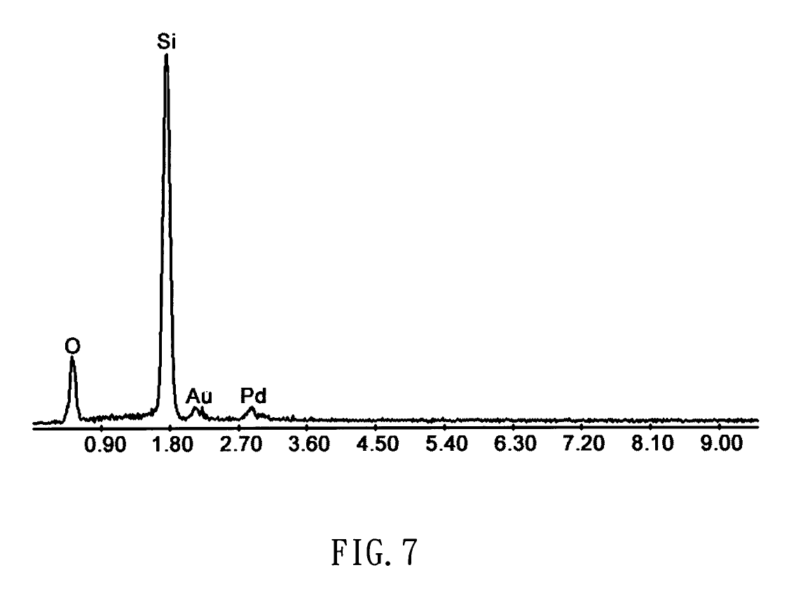

FIG. 6 is a SEM photo of nanowires obtained in a second embodiment of the invention. This photo clearly shows the structure of the nanowires obtained by this embodiment. FIG. 7 shows the results of analyzing the nanowires of the second embodiment by using an energy dispersive x-ray (EDX). As illustrated, the nanowires consist of silicon.

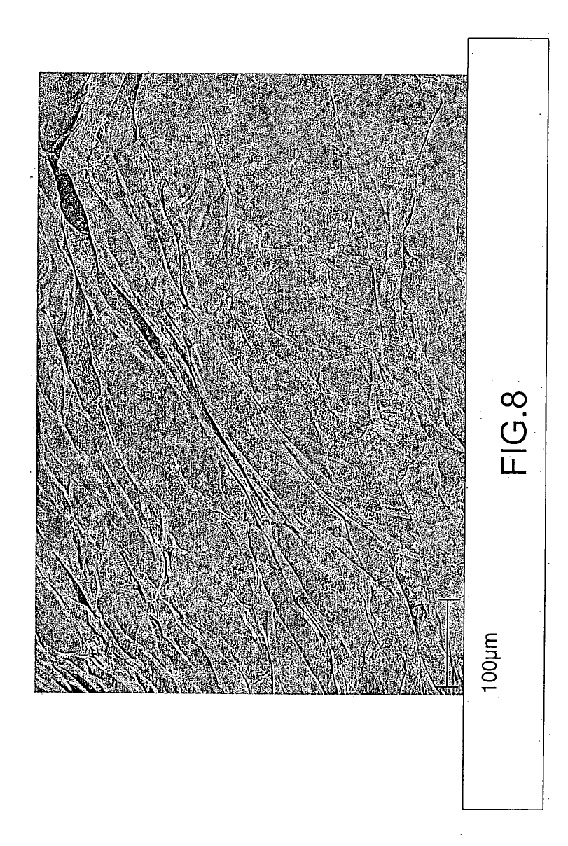

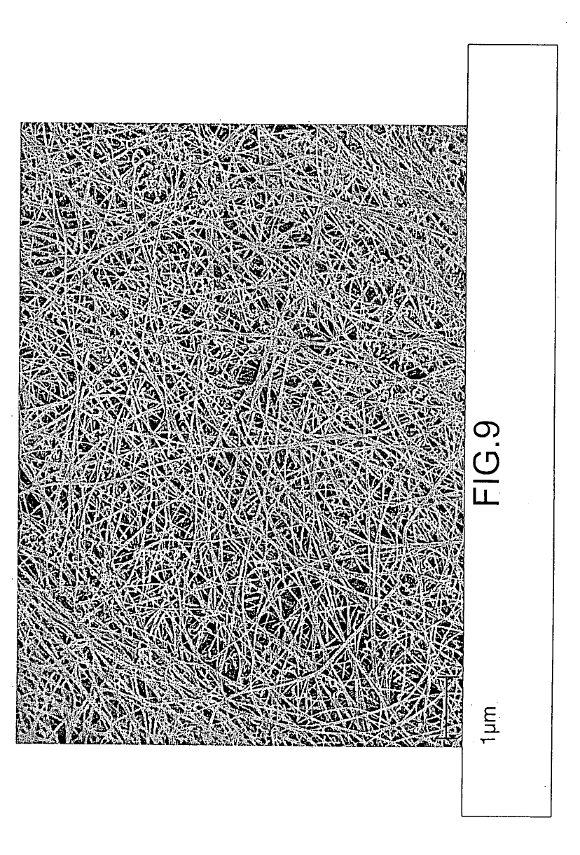

Furthermore, nanowires obtained by the invention can be further made into a two-dimensional structure. The high-surface-oxygen-content silicon powders are uniformly distributed as a thin layer to form a nano film. In a third embodiment, 20 g of high-surface-oxygen-content silicon powders having an average particle diameter of 40 micrometers are placed into a heating chamber. After the chamber is vacuated to 10⁻¹ torr, the temperature of the chamber increases to 1200° C. The reaction gas including 90% argon and 10% mixed gas of hydrogen and acetylene is charged in the chamber, with the atmosphere of the chamber being 30-100 torr. Then, the chamber cools down to form silicon carbide nano films. FIG. 8 and FIG. 9 are SEM photos showing the obtained films with different amplification. It is clear from FIG. 8 that the obtained film is dense. FIG. 9 is an enlarged view of FIG. 8. See FIG. 9, the nano structure constructing of nanowires has an extremely fine porosity, which can be applied in very fine filtering material.

1. A process of forming silicon-based nanowires, comprising:
placing high-surface-oxygen-content silicon powders into a heating chamber, wherein the surface oxygen content is more than 6000 ppm;
vacuating the chamber;
increasing the temperature of the chamber to a reaction temperature;
charging a hydrogen-containing reaction gas in the chamber to form a gas reaction atmosphere; and
cooling down the chamber to form nanowires.

2. The process of claim 1, wherein the silicon powders has surface oxygen content ranged from 6000 to 15000 ppm.

3. The process of claim 1, wherein the silicon powders have particle diameters ranged from 10 to 150 micrometers.

4. The process of claim 1, wherein the silicon powders are uniformly distributed in the chamber as a thin film so that the film can be made into a nano film.

5. The process of claim 1, wherein the silicon powders are made by a high pressure water atomizing process.

6. The process of claim 1, wherein the reaction temperature ranges from 1100° C. [symbol] 1350° C.

7. The process of claim 1, wherein the atmosphere is 0 to 100 torr.

8. The process of claim 1, wherein the reaction gas includes reaction gas including 90% argon and 10% mixed gas of hydrogen and nitrogen.

9. The process of claim 1, wherein the reaction gas includes reaction gas including 90% argon and 10% mixed gas of hydrogen and acetylene.

10. The process of claim 1, further comprising providing a carbon source in the heating chamber for forming SiC nanowires.
